(19) United States
(12) Patent Application Publication
(10) Pub. No.: US 2025/0079171 A1
(43) Pub. Date: Mar. 6, 2025

(54) SUBSTRATE-PROCESSING METHOD AND SUBSTRATE-PROCESSING DEVICE

(71) Applicant: Tokyo Electron Limited, Tokyo (JP)

(72) Inventors: Tatsuya MIYAHARA, Yamanashi (JP); Daisuke SUZUKI, Yamanashi (JP); Yoshihiro TAKEZAWA, Yamanashi (JP)

(21) Appl. No.: 18/816,114

(22) Filed: Aug. 27, 2024

(30) Foreign Application Priority Data
Aug. 29, 2023 (JP) 2023-138890

(51) Int. Cl. H01L 21/02; C23C 16/52; C23C 16/56

(52) U.S. Cl. CPC H01L 21/02664; C23C 16/52; C23C 16/56; H01L 21/02381; H01L 21/0245; H01L 21/02532; H01L 21/02576; H01L 21/0262

(57) ABSTRACT

A substrate-processing method includes: preparing a substrate including an undoped silicon film and a phosphorus-doped silicon film, at least the phosphorus-doped silicon film being exposed on a surface of the substrate; and supplying a halogen gas to the substrate, and, from among the undoped silicon film the phosphorus-doped silicon film, etching and removing the phosphorus-doped silicon film selectively.

### CROSS-REFERENCE TO RELATED APPLICATIONS

This application is based upon and claims priority to Japanese Patent Application No. 2023-138890, filed on Aug. 29, 2023, the entire contents of which are incorporated herein by reference.

### BACKGROUND

### 1. Field of the Invention

The present disclosure relates to a substrate-processing method and a substrate-processing device.

### 2. Description of the Related Art

There is a technique for etching a silicon film using a chlorine gas (see, for example, patent document 1).

### RELATED-ART DOCUMENT

### Patent Document

[Patent Document] Unexamined Japanese Patent Application Publication No. 2017-228580.

### SUMMARY OF THE INVENTION

According to one example of the present disclosure, a substrate-processing method includes: preparing a substrate including an undoped silicon film and a phosphorus-doped silicon film, at least the phosphorus-doped silicon film being exposed on a surface of the substrate; and supplying a halogen gas to the substrate, and, from among the undoped silicon film and the phosphorus-doped silicon film, etching and removing the phosphorus-doped silicon film selectively.

According to the present disclosure, a part of a silicon film can be removed in a selective way.

### BRIEF DESCRIPTION OF THE DRAWINGS

FIG. 1 is a flowchart showing a substrate-processing method according to an embodiment;

FIG. 2A is a cross-sectional view showing a substrate-processing method according to an embodiment;

FIG. 2B is a cross-sectional view showing a substrate-processing method according to an embodiment;

FIG. 3 is a cross-sectional view showing a substrate-processing device according to an embodiment;

FIG. 4 is a diagram showing results of measuring an amorphous silicon film's etching rate; and

FIG. 5 is a diagram showing results of measuring a polysilicon film's etching rate.

### DETAILED DESCRIPTION OF THE PRESENT DISCLOSURE

Hereinafter, non-limiting embodiments of the present disclosure will be described with reference to the accompanying drawings. In the drawings, the same or corresponding members or parts are assigned the same or similar reference symbols, so that duplicate description thereof will be omitted.

### Substrate-Processing Method

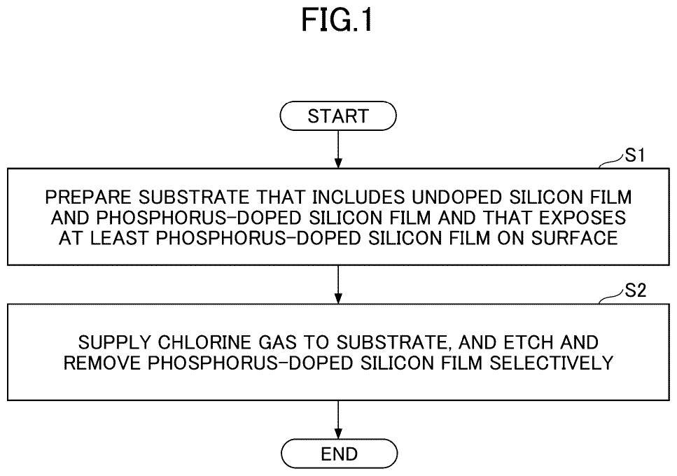

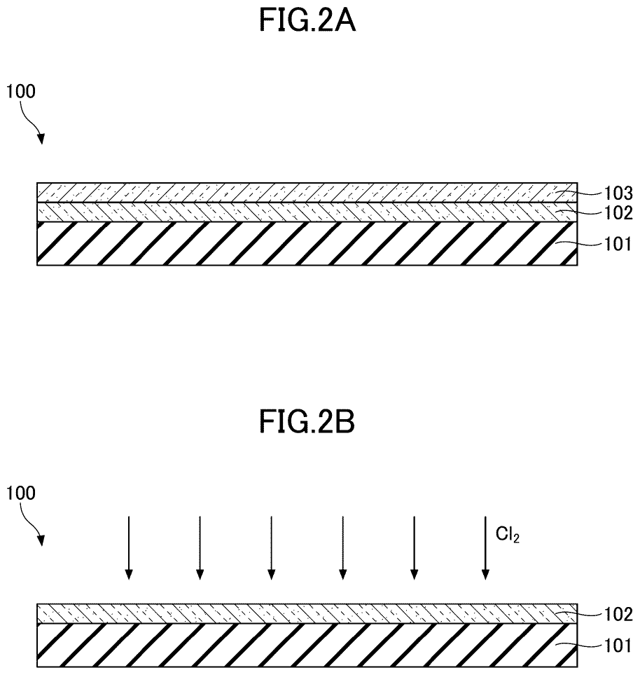

A substrate-processing method according to an embodiment will be described with reference to FIG. 1, FIG. 2A, and FIG. 2B. As shown in FIG. 1, the substrate-processing method according to an embodiment includes a step S1 and a step S2.

In step S1, as shown in FIG. 2A, a substrate 100 is prepared. The substrate 100 includes an undoped silicon film 102 and a phosphorus-doped silicon film 103. At least the phosphorus-doped silicon film 103 is exposed on the surface of the substrate 100. For example, on an underlying substrate 101, the undoped silicon film 102 and the phosphorus-doped silicon film 103 are laminated in the order named.

The substrate 100 is a silicon wafer, for example. The type of the substrate 100 is not particularly limited. The substrate 100 may be a different type of semiconductor wafer.

The underlying substrate 101 is, for example, a silicon oxide film. The type of the underlying substrate 101 is not particularly limited. The underlying substrate 101 may be a different film such as a silicon nitride film.

The undoped silicon film 102 is provided over the underlying substrate 101. The undoped silicon film 102 is an undoped polysilicon film, for example. The undoped polysilicon film can be formed by crystalizing an undoped amorphous silicon film through heat-treatment. The undoped amorphous silicon film can be formed by, for example, chemical vapor deposition (CVD) using a monosilane (SiH₄) gas, which is a silicon-containing gas. The undoped silicon film 102 may be an undoped amorphous silicon film.

The phosphorus-doped silicon film 103 may be provided over the undoped silicon film 102. The phosphorus-doped silicon film 103 may be, for example, a phosphorus-doped polysilicon film. The phosphorus-doped polysilicon film can be formed by crystallizing a phosphorus-doped amorphous silicon film through heat-treatment. The phosphorus-doped amorphous silicon film can be formed by CVD using, for example, a monosilane gas, which is a silicon-containing gas, and a phosphine (PH₃) gas, which is a phosphorus-containing gas. The phosphorus-doped silicon film 103 may be a phosphorus-doped amorphous silicon film.

Step S2 may is performed after step S1. In step S2, as shown in FIG. 2B, a chlorine (Cl₂) gas, which is a halogen gas, is supplied to the substrate 100, and, from among the undoped silicon film 102 and the phosphorus-doped silicon film 103, the phosphorus-doped silicon film 103 is selectively etched and removed. In doing so, it is preferable to adjust the temperature of the substrate 100 (hereinafter referred to as the “etching temperature”) to a temperature at which the etching selectivity of the phosphorus-doped silicon film 103 compared to the undoped silicon film 102 is high. In this case, it is possible to prevent or substantially prevent the undoped silicon film 102 from being etched. The etching temperature be determined, by conducting a preliminary experiment, for example. For example, assuming that the undoped silicon film 102 is an undoped polysilicon film and the phosphorus-doped silicon film 103 is a phosphorus-doped polysilicon film, it is preferable if the etching temperature is between 200 degrees Celsius and 400 degrees Celsius, inclusive. If the etching temperature reaches or exceeds 200 degrees Celsius, it is easier to etch the phosphorus-doped silicon film. If the etching temperature rises above 200 degrees Celsius or falls below 400 degrees Celsius, it is possible to prevent or substantially present the undoped polysilicon film from being etched.

According to the substrate-processing method of the embodiment described above, a substrate 100 is prepared first. The substrate 100 includes an undoped silicon film 102 and a phosphorus-doped silicon film 103. At least the phosphorus-doped silicon film 103 is exposed on the surface of the substrate 100. Next, a chlorine gas is supplied to the substrate 100, and, from among the undoped silicon film 102 and the phosphorus-doped silicon film 103, the phosphorus-doped silicon film 103 is selectively etched and removed. The chlorine gas etches and removes the phosphorus-doped silicon film 103, while keeping the undoped silicon film 102 substantially unetched. Therefore, when the phosphorus-doped silicon film 103 is etched, the undoped silicon film 102 underneath the phosphorus-doped silicon film 103 is allowed to remain there. That is, although the undoped silicon film 102 and the phosphorus-doped silicon film 103 are both present, the phosphorus-doped silicon film 103 alone can be selectively etched and removed.

A case has been described with the above embodiment in which, in step S1, the substrate 100 is prepared such that only the phosphorus-doped silicon film 103 is exposed the surface of the substrate 100, but the present disclosure is by no means limited to this. For example, in step S1, the substrate 100 may be prepared such that the undoped silicon film 102 and the phosphorus-doped silicon film 103 are both exposed on the surface of the substrate 100.

Also, although a case has been described with the above embodiment in which, in step S1, the phosphorus-doped silicon film 103 is formed over the undoped silicon film 102, but the present disclosure is by no means limited to this. For example, it is possible to supply the phosphine gas, without supplying the monosilane gas, to the substrate 100 in which the undoped silicon film 102 is formed over the underlying substrate 101, thereby modifying the surface layer of the undoped silicon film 102 and forming the phosphorus-doped silicon film 103.

Furthermore, although a case has been described with this embodiment in which step S2 is performed after step S1, this is by no means limiting. For example, between steps S1 and S2, a step of immersing the substrate 100 in a diluted hydrofluoric acid (DHF) to remove a native oxide film that may be present over the surface of the phosphorus-doped silicon film 103, may be performed.

### Substrate-Processing Device

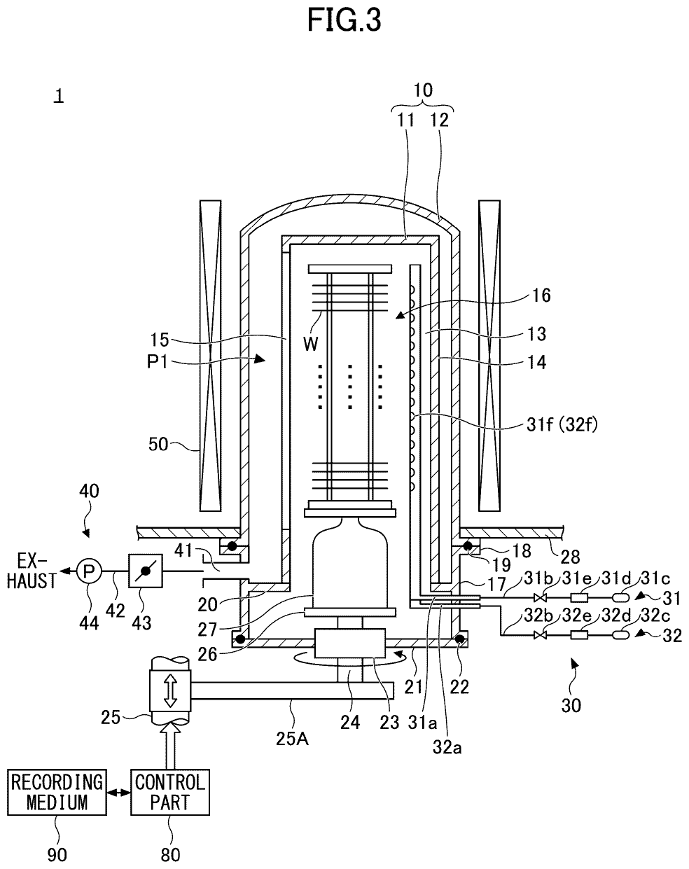

A substrate-processing device 1 according to an embodiment will be described with reference to FIG. 3. As shown in FIG. 3, the substrate-processing device 1 is a batch-type device that processes multiple substrates W at once.

The substrate-processing device 1 includes a process chamber 10, a gas supply 30, an exhauster 40, a heater 50, and a controller 80.

The process chamber 10 can reduce its internal pressure. The process chamber 10 is configured to house the substrates W inside. The process chamber 10 includes an inner tube 11 and an outer tube 12. The inner tube 11 and the outer tube 12 form a cylindrical shape, in which there is a ceiling and the bottom end is open. The outer tube 12 covers the outside of the inner tube 11. The inner tube 11 and the outer tube 12 form a dual-tube structure, in which the inner tube 11 and the outer tube 12 are positioned coaxially. The inner tube 11 and the outer tube 12 are formed of a heat-resistant material such as quartz.

The ceiling of the inner tube 11 may be flat, for example. On one side of the inner tube 11, a housing 13 for housing a gas nozzle is formed in the longitudinal direction (up-and-down direction) of the inner tube 11. For example, a projection 14 is formed by making a part of the side wall of the inner tube 11 project outward, and the inside of the projection 14 is formed to serve as the housing 13.

On the opposite side wall of the inner tube 11, a rectangular opening 15 is formed to face the housing 13 in the longitudinal direction (up-and-down direction) of the inner tube 11.

The opening 15 is a gas exhaustion port that is formed such that the gas in the inner tube 11 can be exhausted through the opening 15. The opening 15 is formed such that the length of the opening 15 is the same as the length of a boat 16 or the opening 15 extends upward and downward so as to be longer than the boat 16.

The bottom end of the process chamber 10 is supported by a cylindrical manifold 17. The manifold 17 is formed of stainless steel, for example. At the top end of the manifold 17, a flange 18 is formed. The flange 18 supports the bottom end of the outer tube 12. Between the flange 18 and the bottom end of the outer tube 12, a seal member 19 such as an O-ring is provided. By this means, the inside of the outer tube 12 is kept airtight.

The inner wall of an upper part of the manifold 17 is provided with an annular support 20. The support 20 supports the bottom end of the inner tube 11. a cover 21 is attached airtight to the opening at the bottom end of the manifold 17, via a seal member 22 such as an O-ring. By this means, the opening at the bottom end of the process chamber 10, that is, the opening of the manifold 17, is sealed airtight. The cover 21 is formed of stainless steel, for example.

At the center of the cover 21, a penetrating rotating shaft 24 is provided via a magnetic fluid seal 23. The lower part of the rotating shaft 24 is rotatably supported by an arm 25A of a raising-and-lowering mechanism 25, which is formed with a boat elevator.

At the top end of the rotating shaft 24, a rotating plate 26 is provided. On the rotating plate 26, the boat 16, retaining the substrates W, is placed via a warming stage 27 formed of quartz. The boat 16 rotates as the rotating shaft 24 rotates. By controlling the raising-and-lowering mechanism 25 to go up and down, the boat 16 moves upward and downward with the cover 21. By this means, the boat 16 is inserted in and removed from the process chamber 10. The boat 16 can be housed in the process chamber 10. The boat 16 retains multiple substrates W (for example, 50 to 150 substrates) substantially parallel, at intervals, in the up-and-down direction.

The gas supply 30 is configured to introduce various processing gases to be used in the above-described substrate-processing method, into the inner tube 11. The gas supply 30 includes a phosphine supply 31 and a monosilane supply 32.

The phosphine supply 31 has a supply tube 31a inside the process chamber 10, and a supply path 31b outside the process chamber 10. In the supply path 31b, a phosphine source 31c, a mass-flow controller 31d, and a valve 31e are provided in sequence, from upstream to downstream, in the direction of the gas flow. By this means, the phosphine gas from the phosphine source 31c is controlled such that its supply timing is controlled by the valve 31e and its flow rate is adjusted to a predetermined rate by the mass-flow controller 31d. The phosphine gas flows into the supply tube 31a through the supply path 31b, and is discharged from the supply tube 31a into the process chamber 10.

The monosilane supply 32 has a supply tube 32a inside the process chamber 10 and a supply path 32b outside the process chamber 10. In the supply path 32b, an monosilane source 32c, a mass-flow controller 32d, and a valve 32e are provided in sequence, from upstream to downstream, in the direction of the gas flow. By this means, the monosilane gas from the monosilane source 32c is controlled such that its supply timing is controlled by the valve 32e and its flow rate is adjusted to a predetermined rate by the mass-flow controller 32d. The monosilane gas flows into the supply tube 32a through the supply path 32b, and is discharged from the supply tube 32a into the process chamber 10.

The supply tubes 31a and 32a are securely attached to the manifold 17. The supply tubes 31a and 32a are formed of quartz, for example. The supply tubes 31a and 32a each extend straight in the vertical direction at a position near the inner tube 11, and bend like the letter “L” and extend in the horizontal direction inside the manifold 17, thereby penetrating the manifold 17. The supply tubes 31a and 32a are provided side by side in the circumferential direction of the inner tube 11. The supply tubes 31a and 32a are formed to have substantially the same height.

In the part where the supply tube 31a is formed inside the inner tube 11, multiple discharge ports 31f are provided. Likewise, in the part where the supply tube 32a is formed inside the inner tube 11, multiple discharge ports 32f are provided.

The discharge ports 31f and 32f are formed at predetermined intervals in the respective directions in which the supply tubes 31a and 32a extend. The discharge ports 31f and 32f release gases in the horizontal direction. The intervals between the discharge ports 31f and 32f are set, for example, the same as the intervals between the substrates W retained in the boat 16. The positions of the discharge ports 31f and 32f in the height direction are set to in-between positions between substrates W that neighbor each other in the up-and-down direction. In this case, the discharge ports 31f and 32f can efficiently supply gases to the opposing surfaces of the neighboring substrates W.

The gas supply 30 may discharge a mixture of multiple gases from a single supply tube. The supply tubes 31a and 32a may be shaped and positioned differently from each other. Also, the gas supply 30 may further include supply tubes for supplying other gases, in addition to phosphine gas and monosilane gas, such as inert gases including nitrogen gas (N₂).

The exhauster 40 exhausts the gas that is exhausted through the opening 15 from inside the inner tube 11 and exhausted from a gas outlet 41 through the space P1 between the inner tube 11 and the outer tube 12. The gas outlet 41 is formed in the side wall of the upper part of the manifold 17, above the support 20. An exhaust path 42 is connected to the gas outlet 41. The exhaust path 42 sequentially includes a pressure adjusting valve 43 and a vacuum pump 44 with a gap therebetween, so that the gas inside the process chamber 10 can be exhausted.

The heater 50 is provided around the outer tube 12. The heater 50 is provided on a base plate 28, for example. The heater 50 has a cylindrical shape so as to cover the outer tube 12. The heater 50 includes, for example, a heat generator, and heats the substrates W in the process chamber 10.

The controller 80 controls the operation of each component of the substrate-processing device 1. The controller 80 may be, for example, a computer. Programs for causing the computer to execute the operations of the components of the substrate-processing device 1 are stored in a recording medium 90. The recording medium 90 may be, for example, a flexible disk, a compact disc, a hard disk, a flash memory, or a digital versatile disc (DVD).

### Operations of Substrate-Processing Device

Operations that take place when the substrate-processing device 1 performs the substrate-processing method according to an embodiment will be described.

First, the controller 80 controls the raising-and-lowering mechanism 25 to transfer the boat 16 retaining multiple substrates W into the process chamber 10, and thereupon the opening at the bottom end of the process chamber 10 is sealed airtight and closed with the cover 21. Subsequently, the controller 80 controls the exhauster 40 to reduce the internal pressure of the process chamber 10, and controls the heater 50 to adjust the temperature of the substrates W to a first film-forming temperature. Each substrate W may be the substrate 100 described above.

Next, the controller 80 controls the heater 50 to maintain the temperature of the substrates W at the first film-forming temperature. In this state, the controller 80 controls the gas supply 30 to supply the monosilane gas to the process chamber 10, and controls the exhauster 40 to maintain the inside of the process chamber 10 at a predetermined pressure. As a result of this, an undoped silicon film 102 is formed over the underlying substrate 101. To form the undoped silicon film 102, it is also possible to supply an inert gas such as nitrogen gas to the process chamber 10 together with the monosilane gas.

Then, the controller 80 controls the heater 50 to adjust the temperature of the substrates W from the first film-forming temperature to a second film-forming temperature. Subsequently, the controller 80 controls the heater 50 to maintain the temperature of the substrates W at the second film-forming temperature. In this state, the controller 80 may control the gas supply 30 to supply the monosilane gas and phosphine gas to the process chamber 10, and control the exhauster 40 to maintain the inside of the process chamber 10 at a predetermined pressure. As a result of this, a phosphorus-doped silicon film 103 is formed over the undoped silicon film 102. To form the phosphorus-doped silicon film 103, it is also possible to supply an inert gas such as nitrogen gas to the process chamber 10 with the monosilane gas and phosphine gas. The second film-forming temperature may be, for example, the same as the first film-forming temperature.

Next, the controller 80 may control the heater 50 to adjust the temperature of the substrates W from the second film-forming temperature to an etching temperature. The controller 80 then controls the heater 50 to maintain the temperature of the substrates W at the etching temperature. In this state, the controller 80 controls the gas supply 30 to supply the chlorine gas to the process chamber 10. The controller 80 also controls the exhauster 40 to maintain the inside of the process chamber 10 at a predetermined pressure. As a result of this, from among the undoped silicon film 102 and the phosphorus-doped silicon film 103, the phosphorus-doped silicon film 103 alone is selectively etched and removed.

Next, the controller 80 may raise the pressure inside the process chamber 10 to the atmospheric pressure and lower the temperature inside the process chamber 10 to an unloading temperature. Subsequently, the raising-and-lowering mechanism 25 is controlled such that the boat 16 is unloaded from the process chamber 10.

### EXAMPLES

### Example 1

First, a substrate (hereinafter referred to as “sample A”) with a phosphorus-doped amorphous silicon film formed over a silicon oxide film, and a substrate (hereinafter referred to as “sample B”) with an undoped amorphous silicon film formed over a silicon oxide film are prepared. The phosphorus-doped amorphous silicon film has a phosphorus concentration of 1×10²¹ atoms/cm³.

Next, the native oxide films on the surfaces of samples A and B are removed using DHF.

Next, the temperature dependencies of the phosphorus-doped amorphous silicon film's etching rate and the undoped amorphous silicon film's etching rate when the chlorine gas is supplied to samples A and B are evaluated using the substrate-processing device 1 described above.

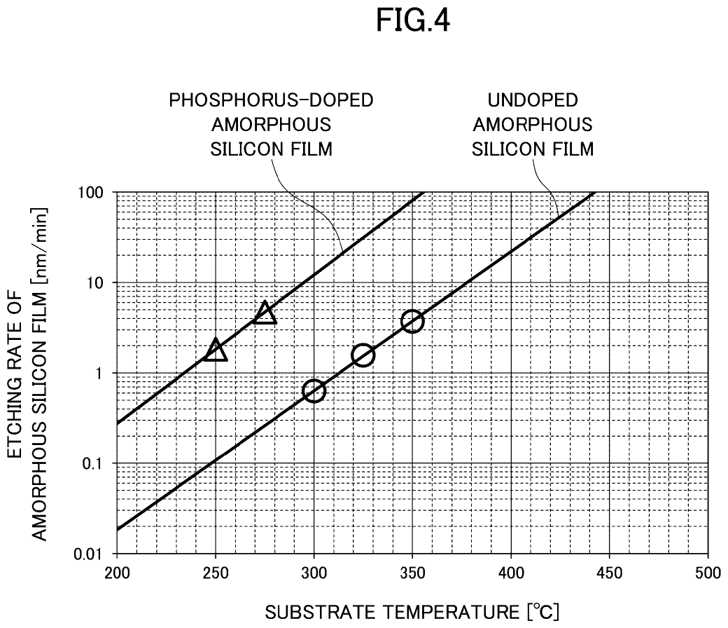

FIG. 4 shows the results of measuring the amorphous silicon films' etching rates. In FIG. 4, the horizontal axis is the substrate temperature [degrees Celsius], and the vertical axis is the etching rate of the amorphous silicon films [nm/min]. Referring to FIG. 4, the triangles are the etching rate of the phosphorus-doped amorphous silicon film, and the circles are the etching rate of the undoped amorphous silicon film.

As shown in FIG. 4, it is clear that the etching rate of the phosphorus-doped amorphous silicon film is several tens of times higher than that of the undoped amorphous silicon film. This result shows that doping an undoped amorphous silicon film with phosphorus makes it possible to remove a part (the phosphorus-doped part) of the amorphous silicon film in a selective way.

### Example 2

First, a substrate (hereinafter referred to as “sample C”) with a phosphorus-doped polysilicon film formed over a silicon oxide film and a substrate (hereinafter referred to as “sample D”) with an undoped polysilicon film formed over a silicon oxide film are prepared. The phosphorus-doped polysilicon film is formed by crystallizing, through heat treatment, a phosphorus-doped amorphous silicon film with a phosphorus concentration of 1×10²¹ atoms/cm³. The undoped film is polysilicon formed by crystallizing an undoped amorphous silicon film through heat treatment.

Next, the native oxide films on the surfaces of samples C and D are removed using DHF.

Next, the temperature dependencies of the phosphorus-doped polysilicon film's etching rate and the undoped polysilicon film's etching rate when the chlorine gas is supplied to samples C and D are evaluated using the substrate processing device 1 described above.

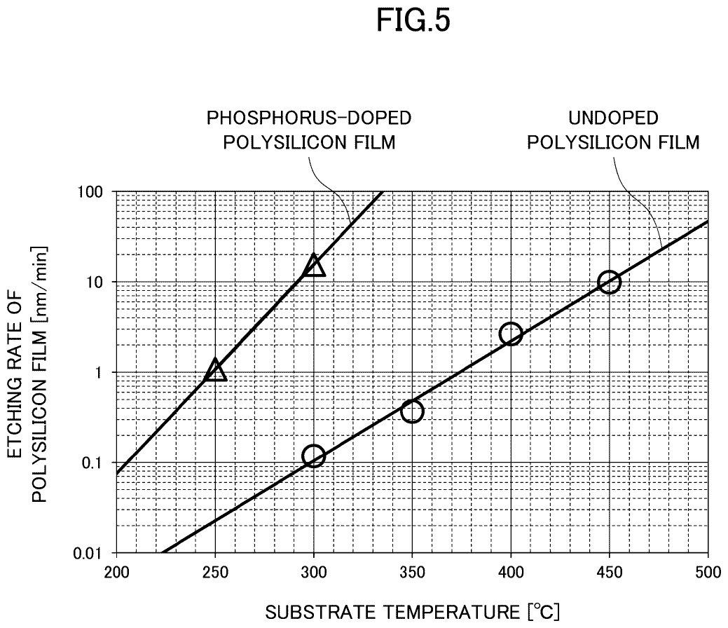

FIG. 5 shows the results of measuring the etching rates of the polysilicon films. In FIG. 5, the horizontal axis is the substrate temperature [degrees Celsius], and the vertical axis is the etching rate of polysilicon film [nm/min]. Referring to FIG. 5, the triangles are the etching rate of the phosphorus-doped polysilicon film, and the circles are the etching rate of the undoped polysilicon film.

As shown in FIG. 5, it is clear that the etching rate of the phosphorus-doped polysilicon film is approximately several tens to several hundred times higher than the etching rate of the undoped polysilicon film. This result shows that doping a polysilicon film with phosphorus makes it possible to remove a part (the phosphorus-doped part) of the polysilicon film in a selective way.

As shown in FIG. 4 and FIG. 5, when polysilicon films are used, the etching selectivity of a phosphorus-doped silicon film relative to an undoped silicon film is higher than when amorphous silicon films are used. Therefore, from the perspective of ensuring high etching selectivity, it is preferable to use a polysilicon film as the silicon film.

It should be understood that the embodiments disclosed herein are illustrative in all respects and not restrictive. Various omissions, substitutions, and changes may be made to the above-described embodiments without departing from the scope of claims recited herein and the spirit of the disclosure.

Although cases have been described with the above embodiments in which the silicon-containing gas is monosilane gas, the present disclosure is by no means limited to this. For example, the silicon-containing gas may be other high-order silane gases such as disilane (Si₂H₆) gas, trisilane (Si₃H₈) gas, tetrasilane (Si₄H₁₀) gas, and so forth. Also, the silicon-containing gas may be a mixture of two or more gases among monosilane gas and high-order silane gases.

Although cases have been described with the above embodiment where the halogen gas is chlorine gas, the present disclosure is by no means limited to this. For example, the halogen gas may be fluorine (F₂) gas or bromine (Br₂) gas.

What is claimed is:

1. A substrate-processing method comprising:
preparing a substrate including an undoped silicon film and a phosphorus-doped silicon film, at least the phosphorus-doped silicon film being exposed on a surface of the substrate; and
supplying a halogen gas to the substrate, and, from among the undoped silicon film and the phosphorus-doped silicon film, etching and removing the phosphorus-doped silicon film selectively.

2. The substrate-processing method according to claim 1, wherein the preparation of the substrate includes forming the phosphorus-doped silicon film over the undoped silicon film.

3. The substrate-processing method according to claim 2, wherein the phosphorus-doped silicon film is formed by chemical vapor deposition using a silicon-containing gas and a phosphorus-containing gas.

4. The substrate-processing method according to claim 1, wherein the preparation of the substrate includes forming the phosphorus-doped silicon film by modifying a surface layer of the undoped silicon film.

5. The substrate-processing method according to claim 1,
wherein the undoped silicon film is an undoped polysilicon film, and
wherein the phosphorus-doped silicon film is a phosphorus-doped polysilicon film.

6. The substrate-processing method according to claim 5, wherein the halogen gas is a chlorine gas.

7. The substrate-processing method according to claim 6, wherein the removal of the phosphorus-doped silicon film includes maintaining the substrate at a temperature between 200° C. and 400° C., inclusive.

8. A substrate-processing device comprising
a process chamber configured to house a substrate,
a gas supply configured to supply a processing gas into the process chamber, and
a controller,
wherein the controller is configured to control the gas supply such that:
a substrate including an undoped silicon film and a phosphorus-doped silicon film is prepared, at least the phosphorus-doped silicon film being exposed on a surface of the substrate; and
a halogen gas is supplied to the substrate, and, from among the undoped silicon film and the phosphorus-doped silicon film, the phosphorus-doped silicon film is etched and removed selectively.
